(19) United States
(12) Patent Application Publication
(10) Pub. No.: US 2024/0174102 A1
(43) Pub. Date: May 30, 2024

(54) COOLING TANK ASSEMBLY FOR A LIQUID COOLING OF A CHARGING STATION FOR ELECTRICALLY POWERED MOTOR VEHICLES, BASE ASSEMBLY FOR A CHARGING STATION IN PARTICULAR COMPRISING SUCH A COOLING TANK ASSEMBLY AND CHARGING STATION COMPRISING SUCH A BASE ASSEMBLY

(71) Applicant: ads-tec Energy GmbH, Nürtingen (DE)

(72) Inventors: Roman MOLCHANOV, Neckartenzlingen (DE); Andreas GREIF, Weilheim (DE)

(21) Appl. No.: 18/511,232

(22) Filed: Nov. 16, 2023

(30) Foreign Application Priority Data
Nov. 24, 2022 (DE) 102022131171.6

(51) Int. Cl. B60L 53/302; B65D 81/38; B67D 7/42; H02J 7/00

(52) U.S. Cl. CPC B60L 53/302; B65D 81/38; B67D 7/42; H02J 7/0042

(57) ABSTRACT

The invention relates to a cooling tank assembly for a liquid cooling of a charging station for electrically powered motor vehicles, comprising a cooling tank and a thermal insulation, which encompasses the cooling tank at least in some sections, whereby the insulation has a flat bottom surface and a top surface, which is at least essentially parallel thereto, as well as a wall connecting the bottom surface to the top surface, whereby the top surface, the bottom surface, and the wall limit a receiving space, in which the cooling tank is arranged.

### CROSS REFERENCE TO RELATED APPLICATIONS

This application claims priority to and the benefit of German Patent Application No. 102022131171.6 filed on Nov. 24, 2022, the entire contents of which are incorporated herein by reference.

The invention relates to a cooling tank assembly for a liquid cooling of a charging station for electrically powered motor vehicles, a base assembly for a charging station in particular comprising such a cooling tank assembly and a charging station comprising such a base assembly.

A charging station for charging an electrically powered motor vehicle is known from the German published patent application DE 10 2017 217 879 A1, the power electronics of which can be cooled with the help of an underground liquid cooling. In the case of charging stations, which can be set up above ground and for the setup of which earth excavation work is not necessary there is also the need for providing an effective and efficient cooling, whereby known concepts in particular have the disadvantage that the costs associated with the logistics, in particular the transport and the arrangement of a cooling tank in a housing of the charging station, are high. Maintenance is generally furthermore complex and complicated, in particular when the cooling tank is arranged in a nested manner in the housing of the charging station.

The invention is based on the object of creating a cooling tank assembly for a liquid cooling of a charging station for electrically powered motor vehicles, a base assembly for a charging station in particular comprising such a cooling tank assembly and a charging station comprising such a base assembly, whereby the mentioned disadvantages are at least reduced, preferably do not occur.

The object is solved in that the present technical teaching is provided, in particular the teaching of the independent claims as well as of the embodiments disclosed in the dependent claims and the description.

The object is solved in particular in that a cooling tank assembly for a liquid cooling of a charging station for electrically powered motor vehicles is created, whereby the cooling tank assembly has a cooling tank.

In one embodiment, the cooling tank assembly in particular additionally has a thermal insulation, which encompasses the cooling tank at least in some sections, preferably completely. The insulation in particular has a flat bottom surface and a top surface, which is at least essentially parallel thereto, in particular parallel, as well as a wall connecting the bottom surface to the top surface. The top surface, the bottom surface, and the wall limit a receiving space, in which the cooling tank is arranged. Advantageously, the insulation can be simultaneously used as packaging for the cooling tank in particular during the transport of the cooling tank. Transport material and packaging material is thus saved in an environmentally friendly manner, and the transport as well as the setup of the cooling tank at the destination point prove to be particularly simple because neither packaging material has to be removed nor additional insulating material has to be applied.

The insulation is in particular formed as packaging, in particular as transport packaging of the cooling tank.

The receiving space in particular has the shape of the cooling tank, so that the cooling tank can be arranged so as to fit tightly in the receiving space.

The wall extends in particular perpendicular to the bottom surface and perpendicular to the top surface. The wall is in particular a circumferential wall of the insulation.

In the context of the present technical teaching, the bottom surface is in particular understood to be a surface of the insulation, which is arranged as intended on a geodetically lower side of the insulation and thus simultaneously of the cooling tank assembly. The top surface is accordingly in particular a surface, which is arranged as intended on a geodetically upper side of the insulation and thus simultaneously of the cooling tank assembly.

The insulation in particular has a cantilever, in particular stackable shape. It is advantageously possible in this way to set up the insulation in a cantilever manner, in particular in a warehouse and/or on a pallet. Advantageously, it is furthermore possible to stack a plurality of insulations in particular comprising a respective cooling tank arranged therein and to thus store and transport them in a space-saving manner, in particular on a pallet.

In one embodiment, the insulation essentially has the shape of a cuboid, or the insulation is designed in such a way that it can be arranged within an imaginary cuboid volume, whereby each surface of the imaginary cuboid is in each case at least contacted by a limiting surface of the insulation. In particular, the insulation is designed so as to be capable of being transported and stacked easily in this way.

With respect to its outer dimensions, the insulation is in particular not larger than a commercially available packaging or a conventional standard pallet.

The insulation in particular has polypropylene, in particular expanded polypropylene or consists of polypropylene, in particular of expanded polypropylene. The insulation can thus advantageously be recycled.

The cooling tank—in particular except for entrances and exits necessary for the operation—is in particular formed to be closed on all sides. Additionally, the insulation—in particular except for necessary feedthroughs for the entrances and exits necessary for operating the cooling tank—are in particular formed to be closed on all sides.

According to a further development of the invention, it is provided that the insulation has two half shells, in particular an upper and a lower half shell, which encompass the receiving space. This represents a simple as well as functional design of the insulation. The two half shells in particular encompass the cooling tank. The half shells in particular each have a complementary shape of the cooling tank on the inside, so that they can be arranged on the outside of the cooling tank so as to fit tightly.

The two half shells in particular engage with one another in such a way that the insulation—in particular except for the necessary feedthroughs for the entrances and exits necessary for operating the cooling tank—is formed to be closed on all sides.

The two half shells are in particular each formed as injection molded part, in particular by means of injection molding.

The cooling tank is in particular configured to receive a cooling liquid, in particular a glycol-water mixture as coolant.

According to a further development of the invention, it is provided that the cooling tank is produced seamlessly using the rotating plastic injection molding process. Advantageously, the cooling tank can be formed to be particularly tight in this way, so that a leakage of coolant directly from the cooling tank can be virtually ruled out.

According to a further development of the invention, it is provided that a ventilation hose is arranged on the cooling tank, which ventilation hose is fluidically, i.e. in terms of flow, connected to an interior of the cooling tank on the one hand and to a surrounding area of the cooling tank on the other hand and which runs along at least one winding—which increases geodetically in particular starting at the cooling tank. Advantageously, it is effectively prevented in this way that coolant can slosh from the filled cooling tank into the surrounding area when the cooling tank is moved. It is advantageously possible in this way to transport the cooling tank in a filled manner. In particular the step of filling at the installation site is no longer necessary.

The ventilation hose is in particular arranged on the cooling tank geodetically on the top. The ventilation hose is in particular connected in terms of flow to a ventilation opening of the cooling tank arranged on the cooling tank geodetically on the top.

In one embodiment, the ventilation hose is formed to be open on both sides. A connection in terms of flow to the surrounding area vie the ventilation hose thus advantageously exists at any time, in particular also during the transport of the cooling tank; an opening of the ventilation hose at the installation site is thus not necessary, so that a ventilation of the cooling tank during the operation of a charging station having the cooling tank is ensured with particularly high safety because the opening by a worker cannot be forgotten.

Advantageously, the ventilation hose can additionally be used for a pressure test of the cooling tank for tightness prior to the filling thereof.

According to a further development of the invention, it is provided that a filling nozzle is arranged on the cooling tank, which filling nozzle is connected in terms of flow to an interior of the cooling tank and which leads into the interior of the cooling tank in a geodetically lower region and which, starting from there, rises in the direction of a filling opening of the filling nozzle. The cooling tank can be filled easily in this way, even without the use of a pump, in particular from a canister or the like. A pump can nonetheless be used in order to increase the flow-through and to fill the tank more quickly.

The filling opening is in particular arranged below a predetermined fill level height of the cooling tank. Advantageously, the cooling tank can be emptied even without a pump in this way according to the principle of the communicating pipes.

In one embodiment, the filling nozzle has a non-return valve and/or a quick coupling in the region of the filling opening.

The object is also solved in that a base assembly for a charging station for electrically powered motor vehicles is created, whereby the base assembly has a support frame, on or in which a cooling tank for receiving coolant and a conveying device for conveying the coolant are arranged. A module, which can be handled, in particular transported, separately from other parts of a charging station, in particular separately from a housing of the charging station, is preferably provided with the base assembly. This simplifies the transport and the setup of the base assembly and of the charging station as well as subsequent maintenance work. The costs associated therewith are thus also low.

The conveying device in particular connected in terms of flow to the cooling tank. The base assembly in particular has at least a first connecting element for the mechanical connection to a housing of a charging station, first fluid connections for the connection of the conveying device and of the cooling tank in terms of flow to coolant lines of the charging station, and first electrical connections for the operative connection to a control device and/or a power supply of the charging station. A quick, modular transport and setup of the charging station can in particular take place in this way.

In one embodiment, the first connecting element is formed as screw element, in particular selected from a group consisting of: A screw bore, a threaded element, in particular a nut or a thread introduced into the support frame, a stud bolt, and a threaded pin.

In one embodiment, the base assembly has a plurality of first connecting elements.

In one embodiment, the first fluid connections are formed as quick couplings or in another suitable way.

In one embodiment, the first electrical connections are formed as plug connectors.

The base assembly in particular has a cooling tank assembly according to the invention or a cooling tank assembly according to one or several of the above-described embodiments. In particular those advantages, which have already been described above in connection with the cooling tank assembly, result in connection with the base assembly.

According to a further development of the invention, it is provided that the base assembly is configured so as to be capable of being set up above ground. Advantageously, excavation work is thus not required in order to set up the base assembly and thus simultaneously the charging station.

According to a further development of the invention, it is provided that the conveying device is mounted in a vibration-damped manner in the support frame. Alternatively or additionally, it is provided that the conveying device is mounted so as to be insulated against structure-borne noises in the support frame. Advantageously, a noise development during the operation of a charging station, which has the base assembly, is in particular reduced in this way during the operation.

A pump group receptacle is in particular arranged on a bottom plate of the support frame via at least one damping element, in particular a plurality of damping elements. In one embodiment, the at least one damping element is screwed to the bottom plate. In one embodiment, the pump group receptacle is formed as bent sheet metal part or is formed from bent sheet metal. A pump group having the conveying device is arranged on, in particular fastened to, the pump group receptacle.

In one embodiment, the pump group can be attached to the pump group receptacle in particular from a front side of the support frame or can be inserted into the pump group receptacle and can be screwed to the pump group receptacle—likewise from the front side—in particular by means of at least one to maximally four screws, in particular by means of three screws.

In one embodiment, the pump group has a sheet metal frame, to which the conveying device is fastened. The sheet metal frame can in particular be attached to the pump group receptacle or can be inserted into the pump group receptacle and can be screwed to the pump group receptacle. In particular on a rear side facing away from the front side, the pump group receptacle has a spring element, in particular a sheet metal spring tongue, which applies a holding force to the sheet metal frame when the sheet metal frame is arranged on the pump group receptacle. In particular, the sheet metal frame can be pushed below the spring element from the front side.

According to a further development of the invention, it is provided that the support frame has handling engagements—which can in particular be accessed from the front side—on both sides. The support frame and thus simultaneously the base assembly can be easily handled, displaced and in particular be set up at an installation site in this way.

The support frame in particular has support elements on both sides, which, in turn, have the handling engagements. The bottom plate is in particular arranged between the support elements and connects the support elements to one another.

In one embodiment, the base assembly additionally has at least one cladding element, which can be arranged on the support frame, for covering the handling engagements and in particular additionally at least the front side. An aesthetic appearance of the base assembly can thus be attained in an advantageous manner for an outside observer.

In one embodiment, the handling engagements are formed as forklift engagements for the engagement of a forklift fork of a forklift. This provides for a particularly simple and simultaneously efficient handling.

According to a further development of the invention, it is provided that the support frame has or forms a collecting tray for collecting at least a portion of the coolant arranged in the cooling tank.

The base plate is in particular formed as collecting tray or forms the collecting tray.

In one embodiment, the base assembly has at least one sensor for detecting liquid, which reaches into the collecting tray and/or for detecting a coolant leakage. In one embodiment, the at least one sensor is selected from a group, consisting of a float switch and a proximity switch.

At least a first sensor of the at least one sensor is in particular arranged in the region of the collecting tray and is configured to detect liquid reaching into the collecting tray, in particular coolant, or water entering from the outside—for example due to a flood. In one embodiment, the first sensor is formed as float switch.

Alternatively or additionally, the base assembly has, as at least one second sensor of the at least one sensor, a fill level sensor, which is arranged and configured to detect a fill level of the coolant in the cooling tank. When coolant escapes from a cooling circuit of the charging station, this can thus be detected via a decrease of the fill level in the cooling tank. In one embodiment, the second sensor is formed as proximity switch—which is in particular arranged on the cooling tank. The proximity switch can advantageously be arranged on the outside of the cooling tank or on the insulation, so that the cooling tank as well as in particular also the insulation can be formed to be closed on all sides.

In one embodiment, the base assembly has the first sensor and the second sensor. At least one event, selected from a coolant leakage and from water entering into the collecting tray from the outside, is in particular recognized on the basis of a combination of sensor signals of the first sensor and of the second sensor. A differentiation between the mentioned events can in particular be made on the basis of the combination of sensor signals:

If a first sensor signal of the first sensor allows drawing the conclusion that liquid entering into the collecting tray, whereby a second sensor signal of the second sensor simultaneously does not suggest a change of the fill level in the cooling tank, a conclusion can be drawn that water enters into the collecting tray from the outside—for example due to a flood with a water level, which is higher than an edge of the collecting tray. If, in contrast, the first sensor signal allows drawing a conclusion to liquid entering into the collecting tray, whereby the second sensor signal simultaneously shows a decrease of the fill level in the cooling tank, a conclusion can be drawn to a coolant leakage. In both cases, the charging station can in particular be turned off for safety reasons.

The object is also solved in that a charging station comprising a housing and a base assembly according to the invention or a base assembly according to one or several of the above-described embodiments is created. The housing is configured to be arranged above the base assembly, in particular on the base assembly. In particular those advantages, which have already been described above in connection with the base assembly or the cooling tank assembly, result in connection with the charging station. In that the base assembly can additionally be arranged below the housing, it is advantageously avoided that coolant escaping from the cooling tank assembly can run into the housing and can negatively impact the electrical components arranged there.

In electrical engineering, any, in particular stationary or mobile device or electrical installation, which serves the purpose of supplying energy to mobile accumulator-operated equipment, machines, or motor vehicles, by means of a simple setting or plugging in, without inevitably having to remove the energy storage—for instance the traction battery of an electric vehicle—is referred to as charging station. Charging stations for electric vehicles are sometimes also referred to as “electricity charging stations” and can comprise several charging points. In particular direct current quick charging systems (high performance charging systems or high power charging systems, HPC systems) such as the so-called combined charging system (CCS), which is common in Europe, are known here. During the generic direct current charging, direct current from the charging station is fed directly into the battery of the vehicle and is, for this purpose, provided to, e.g., solar charging stations by means of a powerful rectifier, preferably of the charging station, from the power supply or by means of large buffer accumulators. A battery management system, which communicates directly or indirectly with the charging station, in order to adapt the current and voltage or to end the process when reaching a predetermined capacity limit, is located in the vehicle. Power electronics are thereby typically located in the charging station. Due to the fact that the DC connections of the charging station are connected directly—without detour via an AC/DC converter of the vehicle—to corresponding connections of the traction battery, high charging currents can be transferred with little loss, which provides for short charging times.

In one embodiment, the charging station is formed as a charging column. The charging station in particular has at least one charging point, in particular exactly one charging point or exactly two charging points.

The charging station is in particular formed as quick charging station. In one embodiment, the charging station is formed as battery-supported charging station, in particular as battery-supported quick charging station.

The housing in particular has at least a second connecting element for the mechanical connection to the base assembly, in particular to the at least one first connecting element.

The housing in particular has a front plate, a rear plate located opposite the front plate, and side parts on both sides, whereby at least one of the side parts is formed as door. In one embodiment, both side parts are formed as doors. The side parts are in particular formed to be slightly longer than the front plate and the rear plate geodetically to the bottom, whereby the side parts conceal the first and second connecting elements when the housing is attached to the base assembly and is mechanically connected to the base assembly.

In one embodiment, the housing has a roof plate, on which in particular at least one lifting element, in particular a lifting eye, is arranged, by means of which the housing can be lifted, in particular lifted off the base assembly or can be lowered onto the base assembly. In one embodiment, the roof plate has four corners and a respective lifting element, in particular a lifting eye, on each corner.

According to a further development of the invention, it is provided that electrical components of the charging station are arranged in the housing, in particular the power electronics and preferably a battery assembly for intermediately storing electrical energy, a control device, additionally in particular second electrical connections for the operative connection of the control device and/or at least one electrical component to the conveying device and in particular to at least one sensor, in particular selected from the first sensor and the second sensor, in particular to the first electrical connections, as well as furthermore in particular cooling lines for cooling the electrical components, as well as second fluid connections for the connection of the cooling lines in terms of flow to the conveying device and the cooling tank, in particular to the first fluid connections.

In one embodiment, the control device is configured to control the conveying device. Alternatively or additionally, the control device is configured to draw a conclusion to at least one event, selected from a coolant leakage and water entering into the collecting tray from the outside, on the basis of at least one sensor signal, in particular selected from a first sensor signal of the first sensor and a second sensor signal of the second sensor. The control device is in particular furthermore configured to end an operation of the conveying device when the at least one event is recognized. An escape of coolant can advantageously be prevented early in this way, which in particular makes it possible in an advantageous manner to design the receiving volume of the collecting tray to be smaller than the volume of the cooling tank. A damage or danger to the charging station or to users of the charging station—in particular caused by electrical short-circuit or high voltage applied in the water in the case of flood—can furthermore be prevented advantageously. The control device is in particular configured to differentiate between the mentioned events on the basis of the combination of sensor signals, in particular as it has already been described above in connection with the base assembly. Alternatively or additionally, the control device is configured to report the at least one detected event to an operator or service of the charging station.

In one embodiment, the second connecting element is formed as screw element, in particular selected from a group, consisting of: A screw bore, a threaded element, in particular a nut or a thread introduced into the housing, a stud bolt, and a threaded pin.

In one embodiment, the housing has a plurality of second connecting elements.

In one embodiment, the second fluid connections are formed as quick couplings or in another suitable way.

In one embodiment, the second electrical connections are formed as plug connectors, in particular complementary to the first electrical connections, which are formed as plug connectors.

The invention will be described in more detail below on the basis of the drawing, in which:

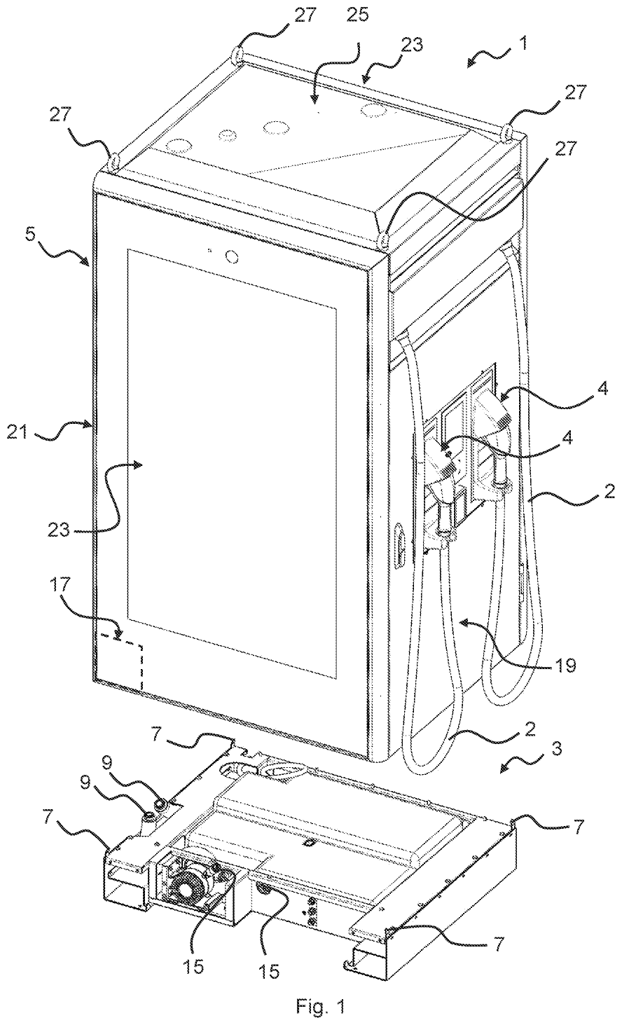

FIG. 1 shows a schematic illustration of an exemplary embodiment of a charging station with an exemplary embodiment of a base assembly;

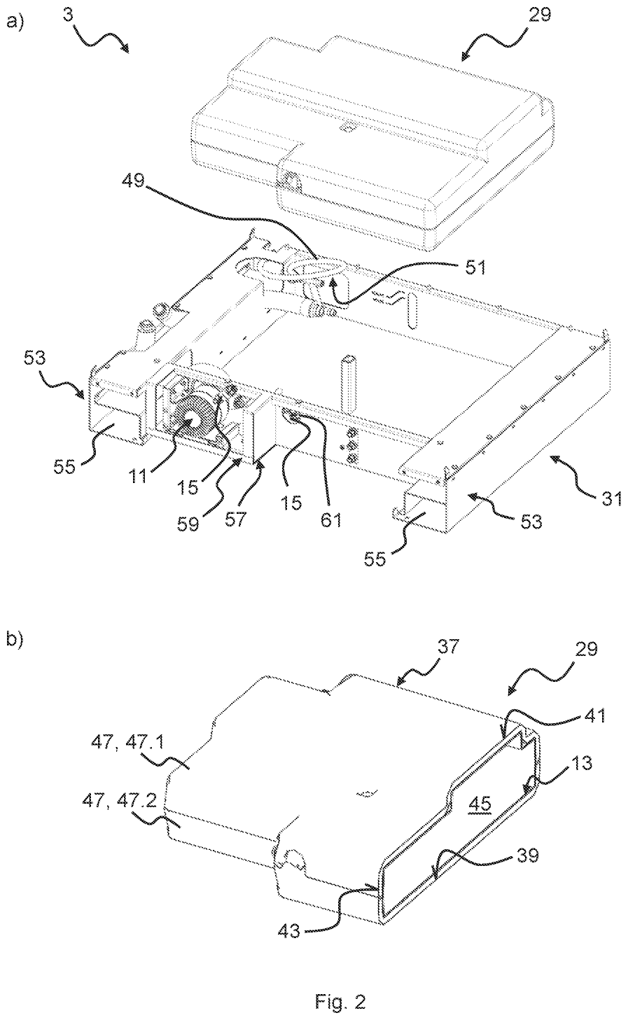

FIG. 2 shows an illustration of the exemplary embodiment of the base assembly;

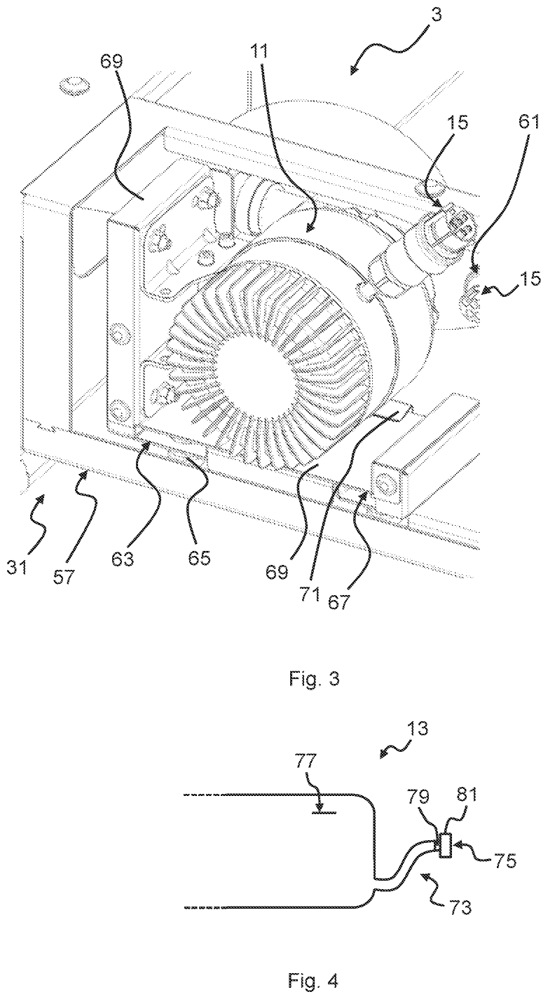

FIG. 3 shows a detail illustration of the exemplary embodiment of the base assembly, and

FIG. 4 shows a detail illustration of a cooling tank of the base assembly.

FIG. 1 shows a schematic illustration of an exemplary embodiment of a charging station 1 with an exemplary embodiment of a base assembly 3.

The charging station 1, which is formed in particular as charging column, has a housing 5 and the base assembly 3, which is in particular set up above ground, in particular at ground level. The housing 5 is configured to be arranged on the base assembly 3. In the case of the exemplary embodiment illustrated here, the charging station 1 has two charging points, each comprising a charging cable 2 comprising a charging plug 4 arranged thereon.

The base assembly 3 in particular has a plurality of first connecting elements 7 for the mechanical connection to the housing 5. The base assembly 3 furthermore also has first fluid connections 9 for connecting a conveying device 11 and a cooling tank 13 illustrated in FIG. 2 in terms of flow to second fluid connections of the charging station 1 as well as first electrical connections 15 for the operative connection to second electrical connections of a control device and/or of a power supply of the charging station 1.

The housing 5 in particular has a plurality of second connecting elements 17 for the mechanical connection to the base assembly 3, in particular to the first connecting elements 7. Only a second connecting element 17 of the second connecting elements 17 is illustrated schematically here.

The housing 5 in particular has a front plate 19, a rear plate 21, and side parts 23 on both sides, whereby the side parts 23 are in particular formed as doors. The housing 5 additionally has a roof plate 25, on which in particular four lifting eyes 27 are arranged.

FIG. 2 shows an illustration of the exemplary embodiment of the base assembly 3 with an exemplary embodiment of a cooling tank assembly 29.

Identical and functionally identical elements are provided with identical reference numerals in all figures, so that reference is in each case made to the preceding description in this respect.

In the case of a), an exploded illustration of the base assembly 3 comprising the cooling tank assembly 29 is illustrated.

The base assembly 3 has a support frame 31 and the cooling tank assembly 29 thereon or therein for receiving coolant as well as the conveying device 11 for conveying the coolant.

In the case of b), the cooling tank assembly 29 is illustrated in a sectional illustration. It has the cooling tank 13 and a thermal insulation 37, which encompasses said cooling tank at least in some sections, preferably completely. The insulation 37 in particular has a flat bottom surface 39 and a top surface 41, which is at least essentially parallel thereto, as well as a wall 43 connecting the bottom surface 39 to the top surface 41. The bottom surface 39, the top surface 41, and the wall 43 limit a receiving space 45, in which the cooling tank 13 is arranged. The insulation 37 simultaneously acts as packaging for the cooling tank 13 during the transport.

The insulation in particular has two half shells 47, namely a first half shell 47.1 and a second half shell 47.2, which encompass the receiving space 45, in particular the cooling tank 13.

Returning to the illustration in a), a ventilation hose 49 is in particular arranged on the cooling tank 13 geodetically on the top, which ventilation hose is connected in terms of flow to an interior of the cooling tank 13 on the one hand and to a surrounding area of the cooling tank 13 on the other hand and which runs along a winding 51, which increases geodetically starting at the cooling tank 13.

The support frame 31 in particular has support elements 53 on both sides, on which handling engagements 55, which are formed as forklift engagements, are formed. A bottom plate 57, which connects the support elements 53 to one another, is arranged between the support elements 53.

The support frame 31 additionally forms or has a collecting tray 59 for collecting at least a portion of the coolant arranged in the cooling tank 13. The bottom plate 57 is in particular formed as the collecting tray 59 or forms the collecting tray 59.

The base assembly 3 in particular has at least one sensor 61, which can be formed as float switch or as proximity switch, for detecting liquid, which reaches into the collecting tray 59 and/or for detecting a coolant leakage.

FIG. 3 shows a detail illustration of the exemplary embodiment of the base assembly 3.

The conveying device 11 is in particular mounted in a vibration-damped manner, in particular so as to be insulated against structure-borne noises, in the support frame 31. A pump group receptacle 63 is in particular arranged on the bottom plate 57 via damping element 65. The pump group receptacle 63 is preferably formed as bent sheet metal part or is formed from bent sheet metal. A pump group 67 having the conveying device 11 is fastened to the pump group receptacle 63. The pump group 67 can in particular be inserted into the pump group receptacle 63 from a front side of the support frame 31 and can be screwed to the pump group receptacle 63—likewise from the front side.

The pump group 63 in particular has a sheet metal frame 69, to which the conveying device 11 is fastened. In particular on a rear side facing away from the front side, the pump group receptacle 63 has a spring element 71, which is in particular formed as a sheet metal spring tongue, which applies a holding force to the sheet metal frame 69 when the sheet metal frame 69 is arranged on the pump group receptacle 63. The sheet metal frame 69 can in particular be pushed below the spring element 71 from the front side.

FIG. 4 shows a detail illustration of the cooling tank 13. A filling nozzle 73 is in particular arranged on the cooling tank 13, which filling nozzle is connected in terms of flow to the interior of the cooling tank 13 and which leads into the interior of the cooling tank 13 in a geodetically lower region and which, starting from there, rises in the direction of a filling opening 75 of the filling nozzle 73. The filling opening 75 is in particular arranged below a predetermined fill level height 77 of the cooling tank 13. In the region of the filling opening 75, the filling nozzle 73 in particular has a non-return valve 79 and/or a quick coupling 81.

1. A cooling tank assembly for a liquid cooling of a charging station for electrically powered motor vehicles, comprising a cooling tank and a thermal insulation, which encompasses the cooling tank at least in some sections, whereby the insulation has a flat bottom surface and a top surface, which is at least essentially parallel thereto, as well as a wall connecting the bottom surface to the top surface, whereby the top surface, the bottom surface, and the wall limit a receiving space, in which the cooling tank is arranged.

2. The cooling tank assembly according to claim 1, whereby the insulation has two half shells, which encompass the receiving space.

3. The cooling tank assembly according to claim 1, whereby the cooling tank is seamlessly produced using the rotating plastic injection molding process.

4. The cooling tank assembly according to claim 1, whereby a ventilation hose is arranged on the cooling tank, which ventilation hose is fluidically connected to an interior of the cooling tank on the one hand and to a surrounding area of the cooling tank on the other hand and which runs along at least one winding—which rises geodetically in particular starting at the cooling tank.

5. The cooling tank assembly according to claim 1, whereby a filling nozzle is arranged on the cooling tank, which filling nozzle is fluidically connected to an interior of the cooling tank and which leads into the interior of the cooling tank in a geodetically lower region and which, starting from there, rises in the direction of a filling opening of the filling nozzle, whereby the filling opening is arranged below a predetermined fill level height of the cooling tank.

6. A base assembly for a charging station for electrically powered motor vehicles, comprising a support frame, on or in which a cooling tank for receiving coolant, in particular a cooling tank assembly according to claim 1, and a conveying device for conveying the coolant are arranged, whereby the conveying device is fluidically connected to the cooling tank, and whereby the base assembly has at least a first connecting element for the mechanical connection to a housing of a charging station, first fluid connections for the fluidic connection of the conveying device and of the cooling tank to coolant lines of the charging station, and first electrical connections for the operative connection to a control device and/or a power supply of the charging station.

7. The base assembly according to claim 6, whereby the base assembly is configured to be capable of being set up above ground.

8. The base assembly according to claim 6, whereby the conveying device is mounted in a vibration-damped manner and so as to be insulated against structure-borne noises in the support frame.

9. The base assembly according to claim 6, whereby the support frame has handling engagements on both sides, in particular forklift engagements for the engagement of a forklift fork of a forklift, whereby the base assembly preferably additionally has at least one cladding element, which can be arranged on the support frame, for covering the handling engagements.

10. The base assembly according to claim 6, whereby the support frame has or forms a collecting tray for collecting at least a portion of the coolant arranged in the cooling tank, whereby the base assembly in particular has at least one sensor for detecting at least one event, selected from liquid, which reaches into the collecting tray and a coolant leakage.

11. A charging station comprising a housing and a base assembly according to claim 6, whereby the housing is configured to be arranged above the base assembly and has at least one second connecting element for the mechanical connection to the base assembly, in particular to the at least one first connecting element.
